(19) United States
(12) Patent Application Publication
(10) Pub. No.: US 2014/0048413 A1
(43) Pub. Date: Feb. 20, 2014

(54) FILM-FORMING APPARATUS

(71) Applicant: ULVAC, INC., Chigasaki-shi (JP)

(72) Inventors: Shuji KODAIRA, Susono-shi (JP); Tomoyuki YOSHIHAMA, Susono-shi (JP); Koukichi KAMADA, Susono-shi (JP); Kazumasa HORITA, Susono-shi (JP); Junichi HAMAGUCHI, Susono-shi (JP); Shigeo NAKANISHI, Susono-shi (JP); Satoru TOYODA, Susono-shi (JP)

(73) Assignee: ULVAC, INC., Chigasaki-shi (JP)

(21) Appl. No.: 14/061,184

(22) Filed: Oct. 23, 2013

Related U.S. Application Data
(62) Division of application No. 13/383,670, filed on Jan. 12, 2012.

(30) Foreign Application Priority Data
Jul. 17, 2009 (JP) 2009-169335

(51) Int. Cl. C23C 14/35

(52) U.S. Cl. CPC C23C 14/35
USPC 204/298.08

(57) ABSTRACT

There is provided a film forming apparatus for forming a coating film on a surface of an object to be processed by using a sputtering method, the film forming apparatus including: a chamber for accommodating the object and a target serving as a base material for the coating film that are placed so as to face each other; an exhaust unit for reducing the pressure inside the chamber; a magnetic field generating unit for generating a magnetic field in front of the sputtering surface of the target; a direct current power supply for applying a negative direct current voltage to the target; a gas introducing unit for introducing a sputtering gas into the chamber; and a unit for preventing the entering of sputtered particles onto the object until the plasma generated between the target and the object reaches a stable state.

### CROSS-REFERENCE TO RELATED APPLICATION

This is a divisional application of U.S. Ser. No. 13/383,670 filed Jan. 12, 2012 which is a U.S. National Phase Application under 35 U.S.C. §371 of International Patent Application No. PCT/JP2010/061980 filed Jul. 15, 2010, which designated the United States and was published in a language other than English, which claims the benefit of Japanese Patent Application No. 2009-169335 filed on Jul. 17, 2009, all of which are incorporated by reference herein.

### TECHNICAL FIELD

The present invention relates to a film forming apparatus for forming a coating film on the surface of an object to be processed, and especially relates to a film forming apparatus employing a sputtering method, which is one type of a thin film formation method.

### BACKGROUND ART

Conventionally, for example, during the film forming process in the fabrication of semiconductor devices, a film forming apparatus employing a sputtering method (hereafter, referred to as a “sputtering apparatus”) has been used. With respect to the sputtering apparatuses used in such applications, due to the miniaturization of wiring patterns in recent years, these methods are required to be capable of forming films with favorable coatability on the fine holes and trenches with high aspect ratio (for example, the depth and width ratio exceeding 3), over the entire surface of the substrate to be treated. In other words, there is a strong demand for the improved coverage.

In a common sputtering apparatus, as a first step for sputtering particles from the target, a negative voltage is applied to the target placed inside a vacuum chamber where argon gas has been introduced (hereafter, referred to as ignition). As a result, the sputtering gas (such as argon gas) is ionized and collides with the target, and the sputtered particles are ejected from the target surface due to the collision. For example, from a target formed of a thin film wiring material such as Cu, Cu atoms are ejected as sputtered particles and adhered onto a substrate to form a thin film. The substrate serving as an object to receive the deposition is placed opposite the target with a predetermined distance therefrom in a vacuum chamber.

Further, in a DC magnetron sputtering apparatus, a magnetic field is formed on the surface of the target by a magnetic field generating unit (such as a permanent magnet) provided in the back surface of the target. On that basis, by applying a negative voltage to the target, the target surface is collided with the sputtering gas ions, thereby ejecting the atoms of a target material and secondary electrons. By revolving the secondary electrons within the magnetic field formed on the target surface, the frequency of ionization collision between the sputtering gas (an inert gas such as argon gas) and the secondary electrons is increased and the plasma density is also enhanced, thereby allowing the formation of thin films (for example, refer to Patent Document 1).

### PRIOR ART DOCUMENTS

### Patent Documents

[Patent Document 1] Japanese Unexamined Patent Application, First Publication No. 2008-47661

### DISCLOSURE OF INVENTION

### Problems to be Solved by the Invention

The applicants have found that during the film formation on fine holes and trenches, the film formation process, immediately after applying a negative potential to the target, when the plasma has not been stabilized, significantly affects the occurrence of aggregates on the sidewalls of fine holes and trenches. This aggregation may be caused by the quality of films formed at an early stage by the sputtered particles before the plasma has been stabilized. Due to the defects in film quality at early stages, film formation following the plasma stabilization is adversely affected, which results in poor film quality.

Before the progress in wiring pattern miniaturization, since the overall thickness of deposited film has been relatively thick, the amount of film formed during the ignition has been relatively small, and thus did not cause any problem. However, due to the miniaturization of wiring patterns in recent years, the thickness of the film formed at the time of ignition with respect to the required film thickness is no longer negligible.

The present invention has been developed in view of the circumstances described above, and has an object of providing a film forming apparatus that is capable of forming films with favorable coatability on each of the fine holes and trenches with high aspect ratio that are formed on top of the substrate, without being affected by the sputtered particles deposited during the ignition.

### Means for Solving the Problems

A film forming apparatus according to an aspect of the present invention is a film forming apparatus for forming a coating film on the surface of an object to be processed by using a sputtering method, and includes: a chamber for accommodating the object and a target serving as a base material for the coating film that are placed so as to face each other; an exhaust unit for reducing the pressure inside the chamber; a magnetic field generating unit for generating a magnetic field in front of the sputtering surface of the target; a direct current power supply for applying a negative direct current voltage to the target; a gas introducing unit for introducing a sputtering gas into the chamber; and a unit for preventing the entering of sputtered particles onto the object until the plasma generated between the target and the object reaches a stable state.

The unit may be a shutter placed between the object and the target.

Alternatively, the unit may be a transport device for moving the object below the target in the horizontal direction.

Further, the unit may be a grid electrode capable of forming an electric field between the object and the target.

In addition, the unit may be a magnetic field generating unit for forming a magnetic field between the object and the target so as to deflect the trajectory of sputtered particles from the object.

### Effects of the Invention

According to an aspect of the present invention, by including a unit for preventing the entering of sputtered particles onto the object until the plasma reaches a stable state in a film forming apparatus for forming a coating film on the surface of an object to be processed using a sputtering method, films can be formed with favorable coatability on each of the fine holes and trenches with high aspect ratio that are formed on the substrate without being affected by the sputtered particles deposited during the ignition.

When a shutter placed between the object and the target is employed as the unit, film formation can be carried out without the adverse effects from the sputtered particles during ignition since the shutter blocks the sputtered particles.

### BRIEF DESCRIPTION OF THE DRAWINGS

FIG. 1 is a cross sectional view schematically illustrating the structure of a film forming apparatus including a shutter.

FIG. 2A is a cross sectional view schematically illustrating the structure of a film forming apparatus including a split shutter.

FIG. 2B is a cross sectional view schematically illustrating the structure of a film forming apparatus including a split shutter.

FIG. 3A is a cross sectional view schematically illustrating the structure of a film forming apparatus including a movable shutter.

FIG. 3B is a cross sectional view schematically illustrating the structure of a film forming apparatus including a movable shutter.

FIG. 4A is a cross sectional view schematically illustrating the structure of a film forming apparatus including a movable stage.

FIG. 4B is a cross sectional view schematically illustrating the structure of a film forming apparatus including a movable stage.

FIG. 5 is a cross sectional view schematically illustrating the structure of a film forming apparatus including a continuous stage.

FIG. 6A is a cross sectional view schematically illustrating the structure of a film forming apparatus including a mesh electrode.

FIG. 6B is a plan view schematically showing a mesh electrode.

FIG. 7 is a cross sectional view schematically illustrating the structure of a film forming apparatus including a magnetic field generating coil.

FIG. 8A is a schematic cross sectional view of a fine hole and a trench which have been deposited with high aspect ratio.

FIG. 8B is a schematic cross sectional view of a fine hole and a trench which have been deposited with high aspect ratio.

### EMBODIMENTS FOR CARRYING OUT THE INVENTION

### First Embodiment

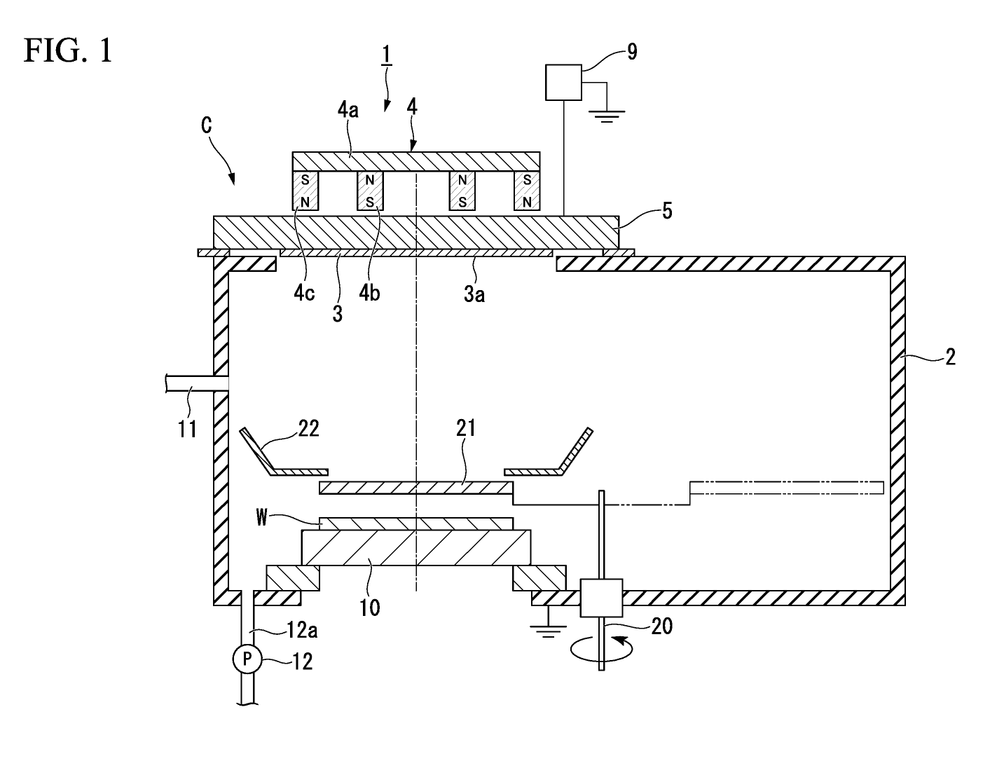

Hereinafter, a film forming apparatus according to a first embodiment of the present invention will be described with reference to the drawings. As shown in FIG. 1, a film forming apparatus 1 adopts a DC magnetron sputtering system and includes a vacuum chamber 2 capable of preparing a vacuum atmosphere. A cathode unit C is mounted on the ceiling of the vacuum chamber 2. It should be noted that in the following descriptions, the ceiling side of the vacuum chamber 2 will be described as “upper” and the bottom side thereof will be described as “lower”.

The cathode unit C includes a target 3, and the target 3 is attached to a holder 5. In addition, the cathode unit C includes a magnetic field generating unit 4 that generates a tunnel-shaped magnetic field in front of a sputtering surface (lower surface) 3a of the target 3. The target 3 is made of a material such as Cu, Ti, Al or Ta which has been appropriately selected in accordance with the composition of the thin film to be formed onto a substrate W which needs to be processed (namely, the object to be processed). The target 3 is made into a predetermined shape (for example, a circular shape in plan view) through a known method in accordance with the shape of the substrate W to be processed, so that the area of the sputtering surface 3a is greater than the surface area of the substrate W. In addition, the target 3 is electrically connected to a DC power supply (sputtering power supply) 9 having a known structure so that a predetermined negative potential is applied thereto.

The magnetic field generating unit 4 is placed on a surface (upper surface) of the target 3 opposite to the sputtering surface 3a. The magnetic field generating unit 4 includes a yoke 4a placed parallel to the target 3, and magnets 4b and 4c that are arranged on the lower surface of the yoke 4a so that the polarities thereof in the target 3 side are different from each other. Note that the shape and number of magnets 4b and 4c are appropriately selected depending on the magnetic field to be formed in front of the target 3 in view of such as the discharge stability and improvements in the efficient use of the target. For example, magnet flakes, rod-shaped magnets, or a suitable combination thereof may be used. Furthermore, the magnetic field generating unit 4 may be formed so as to perform a reciprocating or rotational movement at the back side of the target 3.

A stage 10 is arranged opposite the target 3 at the bottom of the vacuum chamber 2 so as to position and hold the substrate W. In addition, a gas pipe 11 for introducing a sputtering gas such as argon gas is connected to the side wall of the vacuum chamber 2, and the other end thereof is communicated with a gas source through a mass flow controller (not shown). Further, an exhaust pipe 12a, which leads to an evacuation device 12 (exhaust unit) including a turbo molecular pump and a rotary pump, is connected to the vacuum chamber 2.

A rotation shaft 20 is inserted into the bottom wall of the vacuum chamber 2 in an airtight manner, and a shutter 21 is attached to the tip portion thereof. The rotation shaft 20 can be rotated by power of a motor or the like (not shown).

The shutter 21 is disposed between the substrate W and a shield 22. By rotating the rotation shaft 20, the substrate W can be completely covered by the shutter 21 as viewed from the target 3, or the substrate W can also be fully exposed as viewed from the target 3.

Next, film formation using the above-mentioned film forming apparatus 1 will be described.

First, the evacuation device 12 is operated to evacuate inside the vacuum chamber 2 to a predetermined degree of vacuum (for example, a pressure on the order of 10⁻⁵ Pa). Then, after the pressure inside the vacuum chamber 2 reached a predetermined value, the substrate W is set onto the stage 10, and the shutter 21 is arranged above the substrate W. A predetermined negative potential is applied to the target 3 (power input) by a DC power supply 9 to form a plasma atmosphere inside the vacuum chamber 2, while introducing argon gas or the like (sputtering gas) into the vacuum chamber 2 at a predetermined flow rate. In this case, due to the magnetic field from the magnetic field generating unit 4, ionized electrons and secondary electrons produced by sputtering are captured in front of the sputtering surface 3a, thereby increasing the density of plasma in front of the sputtering surface 3a.

Argon ions within the plasma collide with the sputtering surface 3a to sputter the sputtering surface 3a, thereby scattering the atoms and ions (sputtered particles) sputtered from the sputtering surface 3a towards the substrate W. At this stage, since the shutter 21 is placed directly above the substrate W, the sputtered particles are merely deposited on the shutter 21 and do not reach the substrate W.

By rotating the rotation shaft 20 when the initial stage of sputtering is completed and the plasma being stabilized, the shutter 21 moves from directly above the substrate W, thereby exposing the substrate W to the target 3. As a result, the sputtered particles reach the substrate W to start the film formation.

The self-maintaining discharge is possible, particularly in the case of Cu targets. For this reason, following ignition by the introduction of sputtering gas, it is also possible to stop introducing the sputtering gas to wait until the plasma is stably maintained, and then release the shutter 21 to start the film formation on the substrate W.

As described above, by blocking the sputtered particles at an initial stage of sputtering with the shutter 21, sputtered particles when the plasma is in an unstable state do not reach the substrate W. Therefore, it becomes possible to carry out film formation with favorable coatability on each of the fine holes and trenches with high aspect ratio that are formed on top of the substrate.

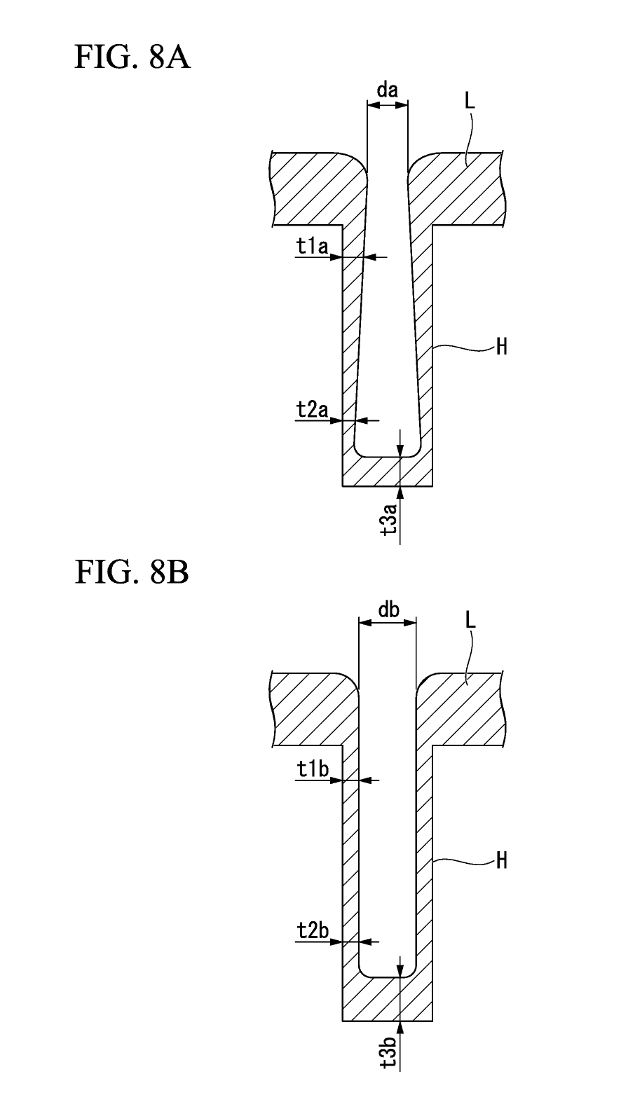

Schematic cross sectional views of fine holes and trenches which have been deposited with high aspect ratio are shown in FIG. 8A and FIG. 8B. In these drawings, the description of H denotes a fine hole with high aspect ratio, and the description of L denotes a deposited thin film. The substrate W to be subjected to a deposition process can be obtained by forming a silicon oxide film (insulating film) I on the surface of Si wafer, followed by patterning of a fine hole H with high aspect ratio within the silicon oxide film.

FIG. 8A is a schematic cross sectional view of a fine hole H when the deposition during ignition has not been blocked, whereas FIG. 8B is a schematic cross sectional view of a fine hole H when the deposition during ignition has been blocked.

In FIG. 8A, it is evident that the film thickness t1a at the upper portion of the fine hole H and the film thickness t2a at the lower portion are unequal. On the other hand, in FIG. 8B, it is clear that the film thickness t1b at the upper portion of the fine hole H and the film thickness t2b at the lower portion are substantially equal due to the interruption of film formation during ignition.

In addition, when the opening diameter da in FIG. 8A is compared with the opening diameter db in FIG. 8B, it is apparent that a larger diameter db is secured in FIG. 8B. Moreover, when the film thickness t3a at the bottom of the fine hole H in FIG. 8A is compared with the film thickness t3b in FIG. 8B, it is clear that a sufficient film thickness t3b is secured in FIG. 8B, thereby improving the bottom coverage.

Furthermore, it is also apparent that roughness (morphology) of the film attached to the sidewall is improved in FIG. 8B compared to FIG. 8A.

### Second Embodiment

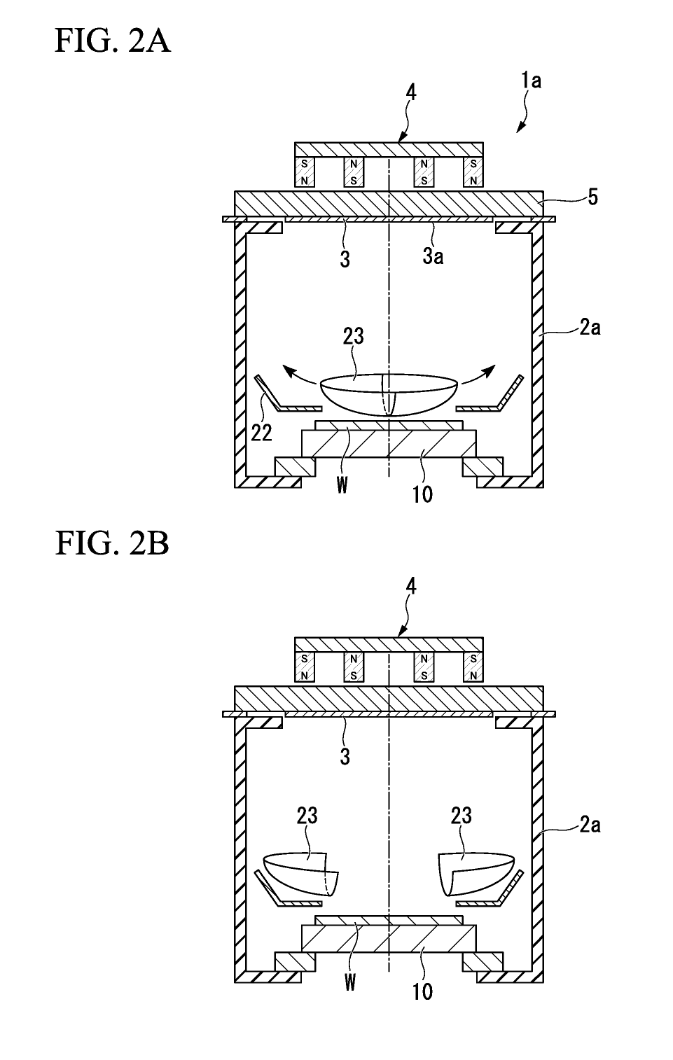

A second embodiment of the present invention that uses a split shutter will be described. Also in the present embodiment, a shutter for blocking the sputtered particles during the ignition has been used as in the first embodiment. The present embodiment has the same structure as that of the first embodiment, with the exception that, regarding the shutter mechanism, a split shutter 23 is used instead of the shutter 21 in the first embodiment. FIGS. 2A and 2B are schematic diagrams of a film forming apparatus 1a including the split shutter 23.

The film forming apparatus 1a includes the split shutter 23 between the target 3 and the substrate W which can be split into two in the center and has a circular shape in plan view. As shown in FIG. 2A, before the split, the split shutter 23 has a size large enough to block the sputtered particles for the substrate W that are ejected from the target 3.

The split shutter 23 has been formed to allow the fluctuation after the split so as to follow an arc shape, and can be opened or closed so as to expose the substrate W to the target 3 after ignition, as shown in FIG. 2B.

The split shutter 23 is placed, when released, in a position along the side wall of the vacuum chamber 2, which results in the efficient use of space.

Due to such a structure, the film forming apparatus 1a of the present embodiment is capable of performing film formation with favorable coatability on each of the fine holes and trenches with high aspect ratio that are formed on the substrate W without being affected by the sputtered particles deposited during the ignition.

### Third Embodiment

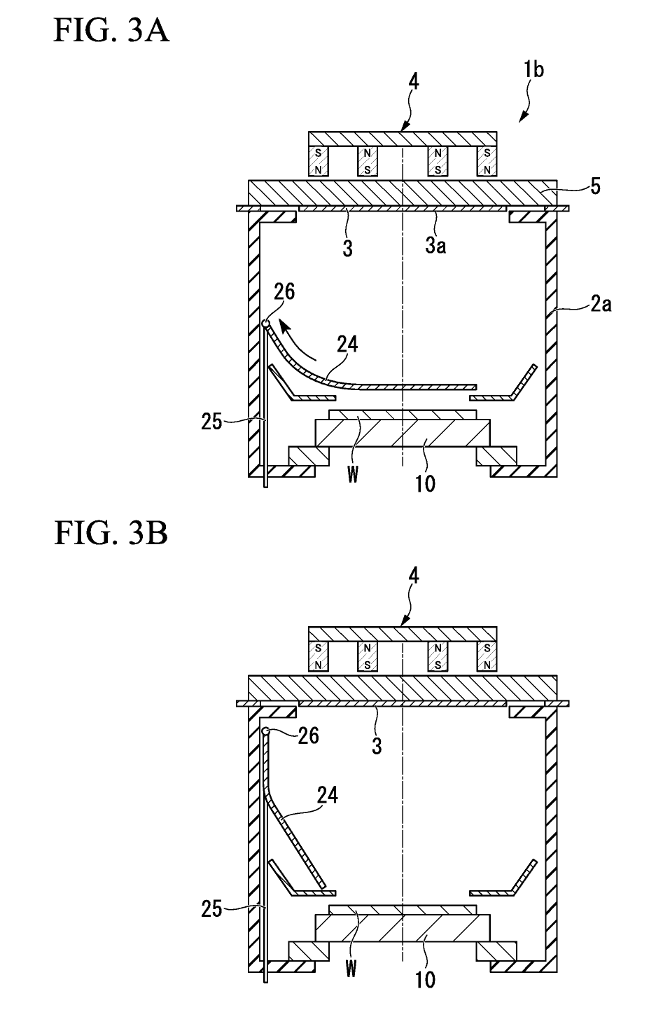

A third embodiment of the present invention that uses a movable shutter will be described. Also in the present embodiment, a shutter for blocking the sputtered particles during the ignition has been used as in the first embodiment. The present embodiment has the same structure as that of the first embodiment, with the exception that regarding the shutter mechanism, a movable shutter 24 is used instead of the shutter 21 in the first embodiment. FIGS. 3A and 3B are schematic diagrams of a film forming apparatus 1b including the movable shutter 24.

The film forming apparatus 1b is characterized by installing the movable shutter 24 between the target 3 and the substrate W in a movable manner.

The movable shutter 24 has a plate form with a rectangular shape in plan view, and one side thereof is linked to a movable shaft 25 via a hinge portion 26. The movable shaft 25 is inserted through the bottom wall of the chamber 2 in an airtight manner and is formed so as to be movable vertically by a power unit (not shown).

FIG. 3A is a diagram when the movable shaft 25 is at the lowermost position, and the movable shutter 24 is guided to immediately above the substrate W by a guide (not shown) so as not to expose the substrate W to the target. FIG. 3B is a diagram when the movable shaft 25 is at the uppermost position, and the movable shutter 24 is rotated around the hinge portion 26 along the side wall of the chamber 2a. As a result, the substrate W is exposed to the target 3, thereby enabling the sputtered particles to reach the substrate W.

### Fourth Embodiment

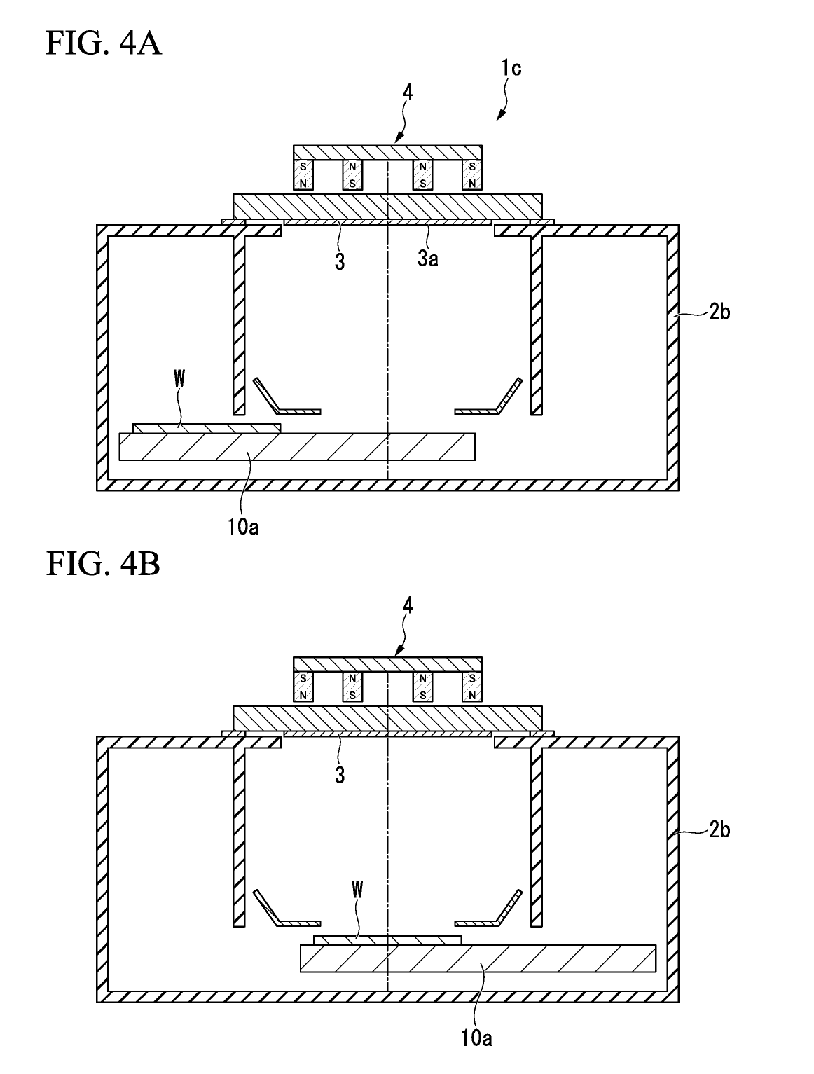

A fourth embodiment of the present invention that uses a movable stage 10a (transport device) will be described. FIGS. 4A and 4B are schematic diagrams of a film forming apparatus 1c including the movable stage 10a.

The movable stage 10a is located at the bottom of the vacuum chamber 2b, and can position and hold the substrate W, as in the first embodiment. The movable stage 10a is formed so as to be freely movable in the horizontal direction by a power unit (not shown). In addition, the movable stage 10a can be moved to a position so that the substrate W is not exposed to the target 3, as shown in FIG. 4A, or to a position so that the substrate W is exposed to the target 3, as shown in FIG. 4B.

Next, film formation using a film forming apparatus 1c having the above-mentioned structure will be described.

First, the substrate W is set onto the movable stage 10a. In this case, the substrate W is placed in a position so as not to be exposed to the target 3. Then, a predetermined negative potential is applied to the target 3 (power input) by a DC power supply to form a plasma atmosphere inside the vacuum chamber 2.

Argon ions within the plasma collide with the sputtering surface 3a to sputter the sputtering surface 3a, thereby scattering the atoms and ions (sputtered particles) sputtered from the sputtering surface 3a towards the substrate W. At this stage, since the substrate W is placed in a position so as not to be exposed to the target 3, the sputtered particles do not reach the substrate W.

The movable stage 10a is moved when the initial stage of sputtering is completed and the plasma being stabilized. When the substrate W held on top of the movable stage 10a is moved to the center of the vacuum chamber 2b in plan view, the substrate W is exposed to the target 3. As a result, the sputtered particles reach the substrate W to start the film formation.

As described above, by placing the substrate W in a position so as not to expose to the target 3 in an initial stage of sputtering, sputtered particles when the plasma is in an unstable state do not reach the substrate W. Therefore, it becomes possible to carry out film formation with favorable coatability on each of the fine holes and trenches with high aspect ratio that are formed on top of the substrate W.

### Fifth Embodiment

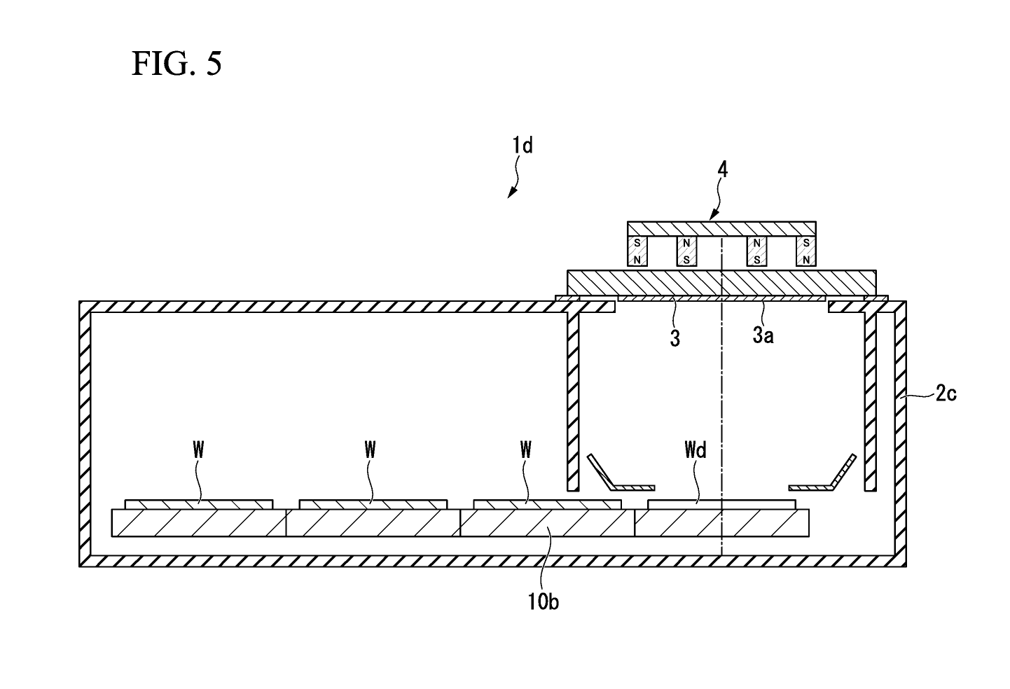

A fifth embodiment of the present invention that uses a continuous stage 10b (transport device) will be described. Also in the present embodiment, the substrate W is placed in a position so as not to be exposed to the target 3 at the time of ignition (i.e., in an initial stage of sputtering), as in the fourth embodiment. The present embodiment has the same structure as that of the first embodiment, with the exception that regarding the transport device, a continuous stage 10b is used instead of the movable stage 10a in the fourth embodiment. FIG. 5 is a schematic diagram of a film forming apparatus 1d including the continuous stage 10b.

The continuous stage 10b has a structure in which multiple stages are combined, and is located at the bottom of the vacuum chamber 2c. The continuous stage 10b is freely movable circularly within the vacuum chamber 2c like a belt conveyor. On each of the stages that form the continuous stage 10b, the substrate W is mounted. However, note that a dummy substrate Wd is mounted on the first stage.

Film formation using the above-mentioned film forming apparatus 1d will be described.

First, the substrate W is set onto the respective stages that form the continuous stage 10b. The dummy substrate Wd is mounted on the first stage. A predetermined negative potential is applied to the target 3 (power input) from a DC power supply to form a plasma atmosphere inside the vacuum chamber 2.

Argon ions within the plasma collide with the sputtering surface 3a to sputter the sputtering surface 3a, thereby scattering the atoms and ions (sputtered particles) sputtered from the sputtering surface 3a towards the substrate W. At this stage, the sputtered particles are deposited on the dummy substrate Wd to form a film.

By moving the continuous stage 10b when the initial stage of sputtering is completed and the plasma being stabilized, the sputtered particles are deposited on the substrate W from the plasma in a stable state to form a film. The continuous stage 10b moves when the deposition on the substrate W is completed. Since the sputtering process has been carried out continuously, for the next substrate W, the sputtered particles scattered from the sputtering surface 3a which has been sputtered by the plasma in a stable state from the start are deposited.

By carrying out film formation using the film forming apparatus 1d, deposition can be performed sequentially on a plurality of substrates W.

### Sixth Embodiment

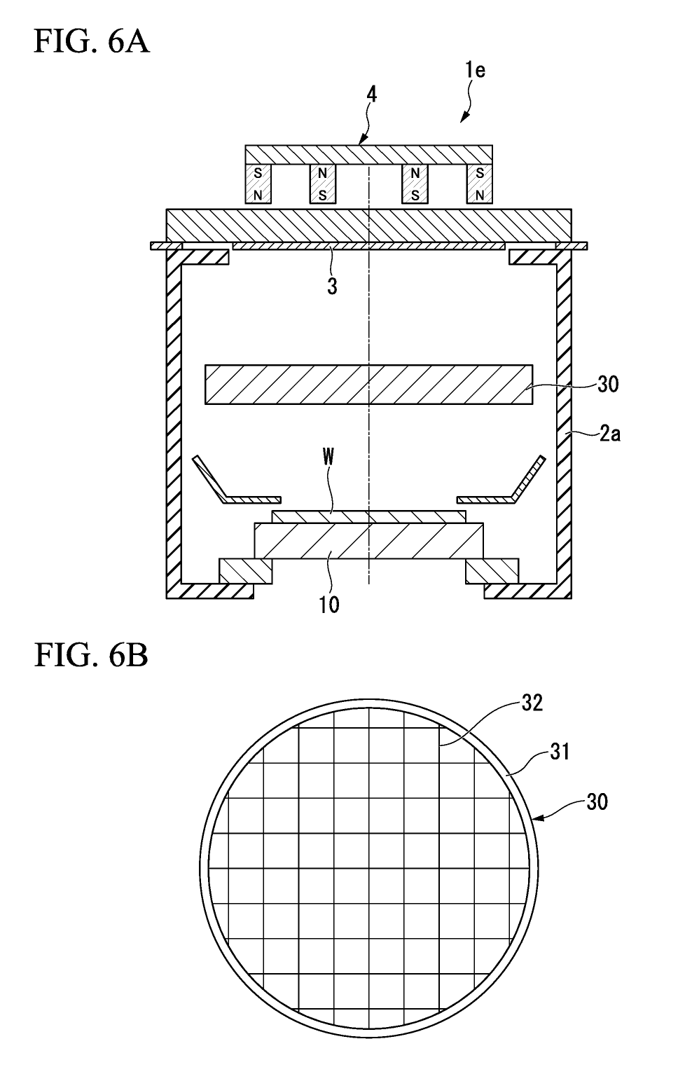

A sixth embodiment of the present invention that uses a mesh electrode (grid electrode) will be described. In the present embodiment, an electrode capable of forming an electromagnetic field is used for blocking the sputtered particles at the time of ignition. The present embodiment has the same structure as that of the second embodiment, with the exception that a mesh electrode 30 is used instead of the split shutter 23 in the second embodiment. FIGS. 6A and 6B are schematic diagrams of a film forming apparatus 1e including the mesh electrode 30.

The film forming apparatus 1e includes the mesh electrode 30 between the target 3 and the substrate W, and the mesh electrode 30 is fixed inside the vacuum chamber 2a in an appropriate manner. FIG. 6B shows a plan view of the mesh electrode 30. The mesh electrode 30 includes a frame body 31 having a circular shape in plan view and conductive wires 32, and the conductive wires 32 are fixed within the frame body 31 in a grid-like manner. The conductive wires 32 to be used are preferably as thin as possible so as not to inhibit the passing of sputtered particles. In addition, the mesh electrode 30 is connected to a power supply which is not shown, and it is possible to form an electromagnetic field by applying a voltage from the power supply.

The film forming apparatus 1e having the above structure forms an electromagnetic field, through the mesh electrode 30, around the mesh electrode 30 at the time of ignition, thereby blocking the sputtered particles and charged particles during deposition at the time of ignition.

In addition, with respect to the mesh electrode 30 used in the film forming apparatus 1e of the present embodiment, since there is no need to use a vacuum chamber with a special shape, it can also be easily introduced into the existing film forming apparatuses.

### Seventh Embodiment

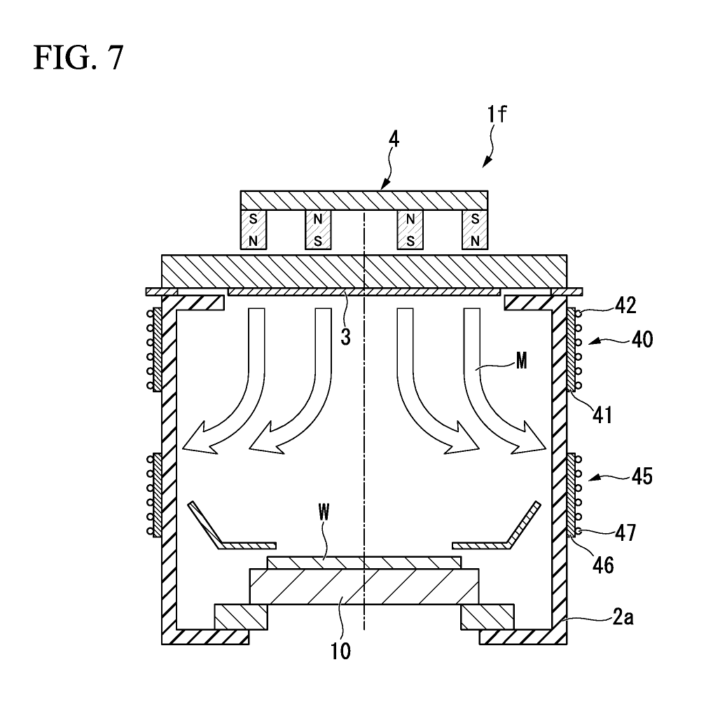

A seventh embodiment of the present invention that uses a coil (magnetic field generating unit) will be described. FIG. 7 is a schematic diagram of a film forming apparatus if including first coils 40 and second coils 45. Here, lines of magnetic force M are indicated using the arrows shown in FIG. 7, for the convenience of explanation.

However, the direction of the magnetic field is not limited by the arrows, and may be N to S (N→S) or S to N (S→N).

In the film forming apparatus 1f, the first coils 40 and the second coils 45 are installed in the periphery so as to surround the vacuum chamber 2a.

The first coils 40 and the second coils 45 have ring-shaped coil supports 41 and 46, respectively, which are provided on the outer wall of the vacuum chamber 2 with a predetermined interval therebetween in the vertical direction. In these coil supports 41 and 46, conductive wires 42 and 47, respectively, are wound around the vertical axis connecting the center of the target 3 and the substrate W. In addition, each of these coils 40 and 45 has a power supply device (not shown) that enables energization of these coils 40 and 45.

Here, the number of coils, the diameter of conductive wires or the number of coil turns is appropriately set in accordance with, for example, the size of the target 3, the distance between the target 3 and the substrate W, the rated current value of the power supply device, or the intensity (Gauss) of magnetic field to be generated.

The power supply device has a known structure which includes a control circuit (not shown) capable of arbitrarily changing the current value and the current direction in the first coils 40 and the second coils 45. In the present embodiment, a negative current is applied to the first coils 40 so as to generate a downward vertical magnetic field. On the other hand, a positive current is applied to the second coils 45 so as to generate an upward vertical magnetic field. By inverting the current value of the second coil 45 from that of the first coil 40 in this manner, as shown in FIG. 7, the direction of lines of magnetic force is not being perpendicular to the substrate W, but heads towards the side wall of the vacuum chamber 2a.

In the film forming apparatus if described above, a positive current is applied to the second coil 45 at the time of ignition while applying a negative current to the first coil 40, thereby forming a magnetic field between the substrate W and the target 3 so as to deflect the trajectory of sputtered particles from the substrate W. As a result, the sputtered particles and charged particles at the time of ignition can be blocked (the direction of the current applied to the first coils 40 and to the second coils 45 may be reversed).

In addition, with respect to the coils 40 and 45 used in the film forming apparatus if of the present embodiment, since there is no need to use a vacuum chamber with a special shape, they can also be easily introduced into the existing film forming apparatuses.

### INDUSTRIAL APPLICABILITY

According to the present invention, there can be provided a film forming apparatus that is capable of forming films with favorable coatability on each of the fine holes and trenches with high aspect ratio that are formed on top of the substrate without being affected by the sputtered particles deposited during the ignition.

### 0 DESCRIPTION OF THE REFERENCE SYMBOLS

C: Cathode unit;

W: Substrate (object to be processed);

1: Film forming apparatus;

2: Vacuum chamber;

3: Target;

3a: Sputtering surface;

4: Magnetic field generating unit;

4a: Yoke;

4b, 4c: Magnet;

9: DC power supply (sputtering power supply);

10: Stage;

10a: Movable stage;

10b: Continuous stage;

11: Gas pipe;

12: Evacuation device;

12a: Exhaust pipe;

20: Rotation shaft;

21: Shutter;

22: Shield;

23: Split shutter;

24: Movable shutter;

25: Movable shaft;

26: Hinge portion;

30: Mesh electrode;

40: First coil;

45: Second coil

What is claimed is:

1. A film forming apparatus for forming a coating film on a surface of an object to be processed by using a sputtering method, the film forming apparatus comprising:
a chamber for accommodating the object and a target serving as a base material for the coating film that are placed so as to face each other;
an exhaust unit for reducing a pressure inside the chamber;
a magnetic field generating unit for generating a magnetic field in front of a sputtering surface of the target;
a direct current power supply for applying a negative direct current voltage to the target;
a gas introducing unit for introducing a sputtering gas into the chamber; and
a unit for preventing entering of sputtered particles to the object until plasma generated between the target and the object reaches a stable state, wherein the unit is a magnetic field generating unit for forming a magnetic field between the object and the target so as to deflect a trajectory of the sputtered particles from the object.

2-5. (canceled)

1. A film forming apparatus for forming a coating film on a surface of an object to be processed by using a sputtering method, the film forming apparatus comprising:
a chamber for accommodating the object and a target serving as a base material for the coating film that are placed so as to face each other;
an exhaust unit for reducing a pressure inside the chamber;
a magnetic field generating unit for generating a magnetic field in front of a sputtering surface of the target;
a direct current power supply for applying a negative direct current voltage to the target;
a gas introducing unit for introducing a sputtering gas into the chamber; and
a unit for preventing entering of sputtered particles to the object until plasma generated between the target and the object reaches a stable state.

2. The film forming apparatus according to claim 1, wherein the unit is a shutter placed between the object and the target.

3. The film forming apparatus according to claim 1, wherein the unit is a transport device for moving the object below the target in a horizontal direction.

4. The film forming apparatus according to claim 1, wherein the unit is a grid electrode capable of forming an electric field between the object and the target.

5. The film forming apparatus according to claim 1, wherein the unit is a magnetic field generating unit for forming a magnetic field between the object and the target so as to deflect a trajectory of the sputtered particles from the object.
